(19) United States
(12) Patent Application Publication
(10) Pub. No.: US 2025/0006821 A1
(43) Pub. Date: Jan. 2, 2025

(54) NEGATIVE CAPACITANCE TOPOLOGICAL QUANTUM FIELD-EFFECT TRANSISTOR

(71) Applicant: Monash University, Clayton (AU)

(72) Inventor: Michael Sears Fuhrer, Clayton (AU)

(21) Appl. No.: 18/707,515

(22) PCT Filed: Nov. 10, 2022
(86) PCT No.: PCT/AU2022/051338

§ 371 Date: May 3, 2024

(30) Foreign Application Priority Data
Nov. 11, 2021 (AU) 2021903614

(51) Int. Cl. H01L 29/66; H01L 29/16; H01L 29/24; H01L 29/51

(52) U.S. Cl. CPC H01L 29/66977; H01L 29/1606; H01L 29/24; H01L 29/516; H01L 29/6684

(57) ABSTRACT

Disclosed herein is A structure comprising: a top gate electrode and a bottom gate electrode, a channel layer formed from a channel material with a band gap modulable by electric field, the channel layer being electrically insulated from the top gate electrode and the bottom gate electrode and being located adjacent to at least one layer of a negative capacitance material.

### FIELD

The invention relates to an electronic structure that comprises a topological insulator layer located adjacent to at least one layer of a negative capacitance material (such as a ferroelectric material). These structures have particular application as low-voltage field effect transistors.

### BACKGROUND

In transistors, a large fraction of power dissipation occurs due to irreversible charging and discharging of the gate capacitor to turn conduction on and off. Its efficiency is characterized by the sub-threshold swing, such that a transistor with a small sub-threshold swing transitions rapidly between its on (high current) and off (low current) states. The sub-threshold swing is the fundamental critical parameter determining the operation of a transistor in low-power applications such as switches.

In a conventional field-effect transistor, a voltage V_{g} applied to the gate raises an energy barrier E_{g} in the channel which impedes conduction, realizing a switch. The effective sub-threshold swing S* is given by S*=e[dE_{g}/dV_{g}]⁻¹. and it is well-known that thermal activation of carriers in the channel forces S*≥1, often termed “Boltzmann's tyranny”. In a topological quantum field-effect transistor, a voltage difference V_{g} between two gates produces an electric field, and induces a sublattice potential difference λᵥ which opens a gap E_{g}, which acts as a barrier to conduction. The effective sub-threshold swing S* for a topological transistor is given by S*=e[dE_{g}/dλᵥ]⁻¹, and λᵥ≤V_{g}, S*=1 corresponds to Boltzmann's limit. In the simplest models the gap equates to the potential difference established by the gates λᵥ, and one expects S*≥1. However, Rashba spin-orbit coupling can result in S*<1 in a topological quantum field-effect transistor, making this device promising for low-voltage applications. Potential shortcomings, however, are that λᵥ may be substantially less than V_{g} dues to screening in the topological channel material, and the strength of Rashba spin-orbit coupling is limited.

It is therefore desirable to further reduce the subthreshold swing in topological transistor devices to reduce power dissipation and improve the efficiency of these devices.

It is an object of the invention to address one or more shortcomings of the prior art and/or provide a useful alternative.

Reference to any prior art in the specification is not an acknowledgment or suggestion that this prior art forms part of the common general knowledge in any jurisdiction or that this prior art could reasonably be expected to be understood, regarded as relevant, and/or combined with other pieces of prior art by a skilled person in the art.

### SUMMARY OF INVENTION

In a first aspect of the invention there is provided a structure comprising: a top gate electrode and a bottom gate electrode, a channel layer formed from a channel material with a band gap modulable by electric field, the channel layer being electrically insulated from the top gate electrode and the bottom gate electrode and being located adjacent to at least one layer of a negative capacitance material.

In an embodiment, the combined capacitance between the top and bottom gate electrodes is greater than 0. The purpose of balancing the negative capacitance of the negative capacitance material and the positive capacitance of the channel material is to get a net positive capacitance. The net positive capacitance ensures that there is no spontaneous and hysteretic polarization of the negative capacitance material which is undesirable, particularly in transistors.

In a second aspect of the invention there is provided a structure comprising:
a top gate electrode and a bottom gate electrode,
a planar channel layer located between the top gate electrode and the bottom gate electrode, the planar channel layer being separated from the top gate electrode by a first insulating layer and separated from the bottom gate electrode by a second insulating layer;
wherein the planar channel layer is formed from a channel material with a band gap modulable by electric field;
wherein at least one of the first insulating layer and the second insulating layer are formed from a negative capacitance material.

In an embodiment of the first or second aspects, the top gate electrode and the bottom gate electrode are operable to apply an electric field across the channel layer.

In an embodiment of the first or second aspects, the top gate electrode and the bottom gate electrode are operable independently of one another.

In an embodiment, the structure is a layered structure comprising or consisting of the following sequential layered arrangement: the first insulating layer, the planar channel layer, and the second insulating layer; wherein the top gate electrode is in electrical contact with the first insulating layer and the bottom gate electrode is in electrical contact with the second insulating layer.

In an embodiment, both of the first insulating layer and the second insulating layers are formed from the ferroelectric material. The first and second insulating layers may be formed from the same ferroelectric material or different ferroelectric materials. However, it is preferred that the first and second insulating layers are formed from the same ferroelectric material.

In an embodiment of the first and second aspects, the negative capacitance material is a ferroelectric material. Preferably, the ferroelectric material is selected from the group consisting of: Hf_{0.5}Zr_{0.5}O₂, La-doped HfO₂, BiFeO₃, BaTiO₃, PbTiO₃, Pb[ZrₓTi₁₋ₓ]O₃, and In₂Se₃.

In an embodiment, the negative capacitance material exhibits negative capacitance and wherein the channel material exhibits positive capacitance, and the combined capacitance of the channel layer, the first insulating layer, and second insulating layer is greater than 0. As discussed above, the net positive capacitance ensures that there is no spontaneous and hysteretic polarization of the ferroelectric which is undesirable, particularly in transistors. In more detail, the electric field-polarization E-P relationship for the ferroelectric layers may be expressed as E=2α_{FE}P+4β_{FE}P³+O(P⁵), where α_{FE} and β_{FE} are parameters, and O(P⁵) indicates additional terms in powers of P greater than or equal to 5. The condition α_{FE}<0 indicates that the layer has a negative capacitance. Then the total thickness of the ferroelectric layers t_{FE} should be chosen to be as small as practicable but larger than (2|α_{FE}|C_{TI})⁻¹, where C_{TI} is the capacitance per area of the channel layer.

In an embodiment, the first insulating layer is adjacent to the channel layer. Preferably, the first insulating layer has a first planar side adjacent to the channel layer, and an opposite facing second planar side adjacent to the top gate electrode.

In an embodiment, the second insulating layer is adjacent to the channel layer. Preferably, the second insulating layer has a first planar side adjacent to the channel layer, and an opposite facing second planar side adjacent to the top gate electrode.

In an embodiment, the first insulating layer and the second insulating layer are each in physical contact with the planar channel layer, the first insulating layer being arranged on a first side of the planar channel layer and the second insulating layer being arranged on a second side of the planar channel layer.

In an embodiment of the first and second aspects, the structure further comprises a source electrode in electrical contact with the planar channel layer, and a drain electrode spaced apart from the source electrode and in electrical contact with the planar channel layer.

In one form of the above embodiment, the source electrode is in electrical contact with the planar channel layer via a doped semiconductor material, and/or the drain electrode is in electrical contact with the planar channel layer via a doped semiconductor material.

In one form of the above embodiment, the source electrode is formed from a doped semiconductor material and/or the drain electrode is formed from a doped semiconductor material.

In an embodiment of the first and second aspects, the top gate electrode and/or the bottom gate electrode are formed from a metal.

In an embodiment of the first and second aspects, the top gate electrode and the bottom gate electrode are configured to apply an electric field across the channel layer in a direction perpendicular to a plane of the channel layer.

In an embodiment of the first and second aspects, the channel material is selected from the group consisting of: few-layer graphene (preferably bilayer or ABC-stacked trilayer graphene), a two-dimensional semiconductor (preferably monolayer or bilayer blue phosphorene or black phosphorene), a topological material (such as a two-dimensional topological material, where “two-dimensional topological material” refers to the topological material being electronically two-dimensional).

In one form of the above embodiment where the channel material is a topological material, the topological material is in the form of a thin film with a thickness of two unit cells or less.

In one form of the above embodiment where the channel material is a topological material, the topological material exhibits a topological phase transition between a trivial state and a non-trivial state at a critical electric field strength.

In one form of the above embodiment where the channel material is a topological material, the topological material has a staggered honeycomb lattice structure. Preferably, lattice atoms of the staggered honeycomb lattice structure comprise one or more atoms selected from the group consisting of: As, Sb, Bi. Preferably, the staggered honeycomb lattice is of the form X, XY, or XYZ, where X is selected from the group consisting of As, Sb, Bi, and Y and Z are each independently selected from the group consisting of H, Cl, Br, or F.

In one form of the above embodiment where the channel material is a topological material, the topological material is a topological Dirac semimetal. Preferably, the topological Dirac semimetal is selected from the group consisting of: a material of the form A₃Bi where A is an alkali metal, Cd₃As₂.

In one form of the above embodiment where the channel material is a topological material, the topological material is a topological insulator. Preferably, the topological insulator is selected from the group consisting of: a material of the form A₃Bi where A is an alkali metal, HgTe, Bi₂Se₃.

In an embodiment of the first and second aspects, the channel layer is in the form of a thin film having a thickness of less than 10 nm.

In an embodiment of the first and second aspects, the structure is a field effect transistor or a component thereof.

In a third aspect of the invention, there is provided a method of operating a structure according to the first aspect of the invention, the second aspect of the invention, and/or embodiments thereof, and/or forms thereof, the method comprising:
applying or modulating a gate voltage to the top gate electrode and/or the bottom gate electrode to generate or vary an electric field across the channel layer in a direction perpendicular to a plane of the channel layer to alter the bandgap of the channel material in the channel layer.

In an embodiment, altering the bandgap of the channel layer further comprises switching the channel material between a trivial state and a non-trivial or topological state.

In a fourth aspect of the invention, there is provided use of a structure according to the first aspect of the invention, the second aspect of the invention, and/or embodiments thereof, and/or forms thereof in an electrical device.

In a fifth aspect of the invention, there is provided an electrical device comprising the structure according to the first aspect of the invention, the second aspect of the invention, and/or embodiments thereof, and/or forms thereof.

As used herein, except where the context requires otherwise, the term “comprise” and variations of the term, such as “comprising”, “comprises” and “comprised”, are not intended to exclude further additives, components, integers or steps.

Further aspects of the present invention and further embodiments of the aspects described in the preceding paragraphs will become apparent from the following description, given by way of example and with reference to the accompanying drawings.

### BRIEF DESCRIPTION OF DRAWINGS

FIG. 1: Schematic of negative capacitance topological quantum field-effect transistor. (a) Structure of the device. (b) Electrostatic potential energy as a function of distance across the device in “on” (V_{b}=Vₜ=0) and “off” (V_{b}>0, Vₜ<0) states.

FIG. 2: Band diagrams in “on” (topological insulator, upper diagram) and “off” (conventional insulator, lower diagram) states. The conducting helical edge states of the topological insulator are shown in the upper diagram.

FIG. 3: Schematic band diagrams of the unipolar NC-TQFET as a function of gate voltage applied to a single gate V_{g}.

FIG. 4: Bandgap as a function of gate voltage for a bilayer graphene (BLG)-ferroelectric transistor (S*=1), and a NC-TQFET with similar properties modelled on bismuthene with strong spin-orbit coupling (S*=0.568). The modeling results assuming the experimentally measured electric-field-dependent bandgap values for BLG from optical spectroscopy and electronic transport are also shown, along with a tight-binding calculation. The remanent polarization Pᵣ=27.5 μC/cm² corresponds to La-doped HfO₂, and Pᵣ=130 μC/cm² corresponds to tetragonal-like BiFeO₃.

### DESCRIPTION OF EMBODIMENTS

The invention broadly relates to a structure comprising: a top gate electrode and a bottom gate electrode, a channel layer formed from a channel material with a band gap modulable by electric field (such as a topological material), the channel layer being electrically insulated from the top gate electrode and the bottom gate electrode and being located adjacent to at least one layer of a negative capacitance material.

The inventors have found that this structure can be used to form a topological quantum field effect transistor (TQFET) with reduced sub-threshold swing as compared with a similar transistor without the negative capacitance material.

In particular, TQFETs are electric-field effect transistors, where the barrier to conduction is created through an electric field, rather than raising an existing potential barrier in the channel as per conventional metal-oxide-semiconductor field-effect transistors (MOSFET). Thus, a TQFET can take full advantage of electric field amplification by negative capacitance, whereas this is not possible with a conventional MOSFET since the electric field is zero in the channel in the subthreshold region.

In more detail, a conventional MOSFET has a capacitance between channel and gate which is large compared to other parasitic capacitances to the channel. In the subthreshold regime, the capacitance between channel and gate is large compared to the quantum capacitance of the channel. Under these conditions, when a gate voltage is applied, i.e. an electrochemical potential difference between gate and channel, this raises the chemical potential of the channel by the same amount, while hardly changing the electrostatic potential of the channel (the electrochemical potential difference is the sum of these two). Thus, the electrostatic potential difference between gate and channel is minimal, and there is very little electric field induced by the gate voltage. Thus, in a conventional MOSFET, because the electric field is near zero in the subthreshold regime, the device cannot benefit from amplification of the electric field through the use of a negative capacitance in series with a positive capacitance.

In contrast, in a TQFET, electric field is used to modify the bandgap of a channel material. In the subthreshold regime, the increased bandgap will act as an increased activation barrier to electron flow. This is completely different to a MOSFET: rather than using the chemical potential change to create a barrier in a semiconductor with a fixed bandgap, the electric field changes the bandgap in a channel with a fixed chemical potential.

The inventors have found that TQFET devices can benefit from amplification of the electric field through the use of a negative capacitance in series with a positive capacitance. This can be accomplished by nearly balancing the positive capacitance of the channel itself with the negative capacitance of a ferroelectric to produce a net positive capacitance (noting that the net positive capacitance ensures that there is no spontaneous and hysteretic polarization of the negative capacitance material). The electric field amplification becomes very large when this balance is near perfect. Advantageously, this amplification of the electric field means that the change in bandgap will be larger for a given change in gate voltage, and thus the subthreshold swing will be smaller.

The invention will be generally described below in relation to a preferred embodiment thereof in the form of a negative capacitance topological quantum field effect transistor (NC-TQFET).

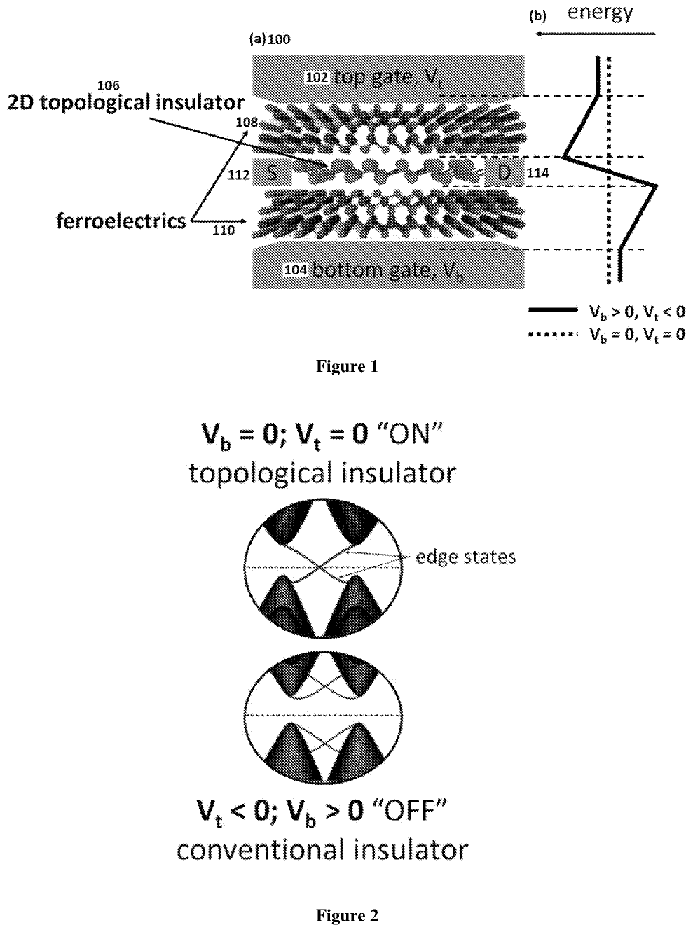

FIG. 1a is an illustration of an NC-TQFET according to one embodiment of the invention. The NC-TQFET 100 includes independent top 102 and bottom gates 104, a channel formed from a 2D layer of a topological insulator (TI) 106 sandwiched between ferroelectric layers 108 and 110, and source electrode 112 and drain electrode 114 in electrical contact with channel 106.

The inventors have found that the combined structure of ferroelectric (negative capacitance) and 2D TI (positive capacitance) amplifies the electric field in the 2D TI layer as illustrated in FIG. 1b. FIG. 1b shows the electrostatic potential energy as a function of distance across the device in “on” state where there is zero voltage applied to bottom gate 104 and top gate 102 (e.g. V_{b}=Vₜ=0), and “off” state where the voltage applied to bottom gate 104 is greater than zero and the voltage applied to top gate 102 is less than zero (e.g. V_{b}>0, Vₜ<0).

FIG. 2 shows band diagrams for the TI in “on” (topological insulator, upper diagram) and “off” (conventional insulator, lower diagram) states. With reference to FIG. 2, the NC-TQFET is in the “on” state when the two top gate voltages V_{b}=Vₜ=0; the potential across the ferroelectric/2D TI/ferroelectric structure is constant, the electric field in the 2D TI is zero, and the 2D TI is in a topological state. Applying gate voltages V_{b}>0, Vₜ<0 places the NC-TQFET in the “off” state, amplifying the electric field in the 2D TI, and opening a conventional bandgap and producing the potential profile shown in the “off” state in the lower diagram of FIG. 2.

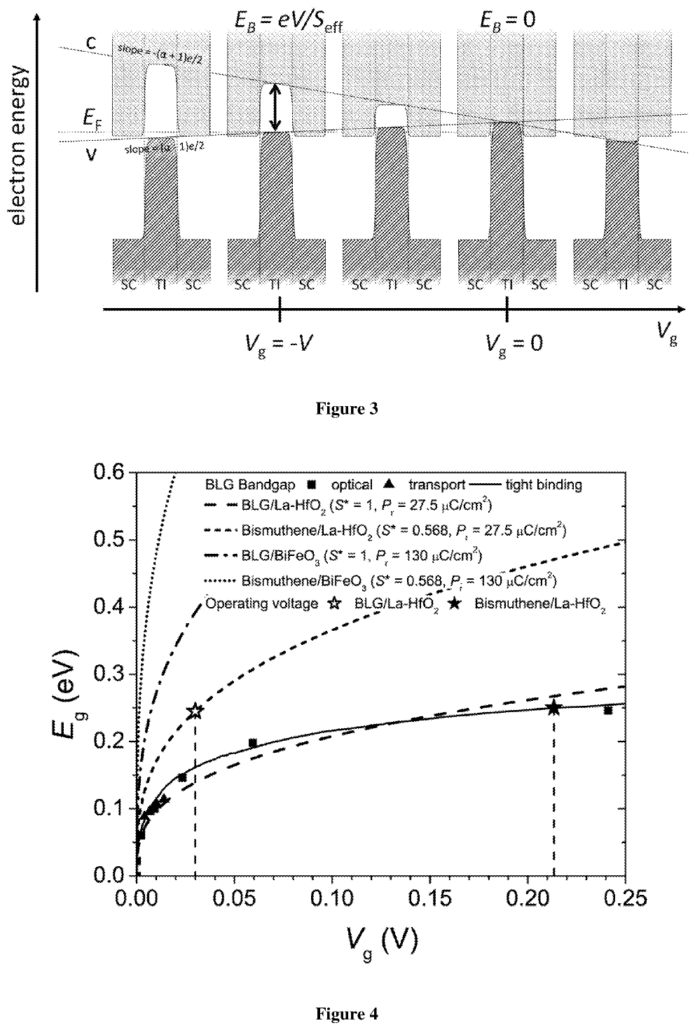

The NC-TQFET described above is ambipolar, turned off by either V_{b}>0, Vₜ<0 or V_{b}<0, Vₜ>0. Ideally an FET device should operate with a single gate as a unipolar transistor. This situation is realized by grounding one gate and applying a gate voltage to the other. Furthermore, if the NC-TQFET channel is connected to semiconducting source/drain leads, unipolar conduction results. FIG. 3 illustrates schematic band diagrams of the unipolar NC-TQFET as a function of gate voltage applied to a single gate V_{g}. At V_{g}=0 the electric field is zero and the device is “on”. At V_{g}<0 the electric field is non-zero, opening a bandgap, and the net effect of the two gates is to shift the overall potential by and amount V_{g}/2. This allows a bandgap eV/S* to be opened at a gate voltage V.

To estimate the electric field amplification in the device illustrated in FIG. 1a, the electric field-polarization E-P relationship for the ferroelectric layer can be approximated as E=2α_{FE}P+4β_{FE}P³ where α_{FE}<0 and β_{FE}>0 are parameters that characterize the ferroelectric. A negative value of a indicates a bistable P(E) relationship i.e. ferroelectricity. The TI layer has E=2α_{TI}P with α_{TI}=+1/(2ε) corresponding to a linear dielectric. A relationship between the gate voltage applied across the FE/TI/FE stack, V_{g}, and the surface potential difference across the TI, ψₛ:

$${V}_{g} = ( 1 + {a}_{1} ) {ψ}_{s} + {a}_{2} {ψ}_{s}^{3} .$$

where α₁=α_{FE}/α_{TI} and α₂=(4β_{FE}/α_{TI}³)t_{FE}² where t_{FE} is the ferroelectric total thickness (twice the thickness of top and bottom layer). The maximum electric field amplification is when α_{FE}/α_{TI}=−1 or t_{FE}=(2|α_{FE}|C_{TI})⁻¹. Then V_{g}=((2β_{FE}C_{TI}²)/(|α_{FE}))*ψₛ³=((C_{TI}²)/(Pr²))*ψₛ³ where Pᵣ=sqrt(−α/(2β)) is the remanent polarization.

Modelling was conducted considering bilayer graphene (BLG) as the channel material since this BLG has an experimentally characterized electric-field-dependent bandgap. However, the skilled person will appreciate that the results of this modelling are applicable to a range of topological insulator materials. For the ferroelectric negative capacitance material, La-doped HfO₂ was selected for which an assumed value of Pᵣ=27.5 μC/cm² was used. As above, the skilled addressee will appreciate that a range of other ferroelectric materials could be used, and particularly those based on HfO₂/ZrO₂.

For a material with negligible spin-orbit coupling such as bilayer graphene, S*=1. The electric field is reduced by dielectric screening in the BLG layer by a dielectric constant K. Furthermore, the separation of the atoms in the sublattice tᵥ is smaller than the van der Waals thickness of the layer t_{TI}, which further reduces the sublattice potential difference by an amount tᵥ/t_{TI}, such that λᵥ=(tᵥ/t_{TI}κ)ψₛ, and dE_{g}/dψₛ. For BLG, tᵥ/t_{TI}=0.5, κ=3.6, S*=1 predicts dE_{g}/dψₛ=0.139 which is very close to experimentally measured values from optical spectroscopy and electronic transport. The BLG capacitance Cₛ=0.048 F/m² (assuming κ=3.6, t_{TI}=6.68 A) allows E_{g}(V_{g}) to be calculated for the ferroelectric/BLG/ferroelectric structure (see the solid lower curve in FIG. 4).

Certain materials, such as honeycomb Xene lattices of heavy atoms, experience a strong Rashba spin-orbit interaction due to the gate electric field. As a result, S* can be less than 1. The inventors have found S*<0.75 in existing materials and estimate S* as low as 0.57 in functionalized Bi (see Table 1 below).

TABLE 1
Strength of atomic spin orbit interaction (SOI) ξ, Slater-Koster parameter
Vspσ and sub-threshold swing S* for TQFET based on group-IV and V Xenes

| | ξ (eV) | | | | V_{spσ} | S* |
|---|---|---|---|---|---|---|
| | Free atom | Normalised | Experimental | | (eV) | Δ_{R} ≠ 0 |
| Graphene | 0.006 | 0.009 | — | | 5.580 | 0.999 [0.999] |
| Silicene | 0.028 | 0.044 | (—) | 0.044 | 2.54 | 0.999 [0.999] |
| Germanene | 0.2 | 0.29 | (0.2) | 0.29 | 2.36 | 0.996 [0.993] |
| Stanene | 0.6 | 0.8 | (0.48) | 0.77 | 1.953 | 0.961 [0.934] |

| | | | | | | |
|---|---|---|---|---|---|---|
| Arsenene | 0.26 | (0.36) | 0.421 | — | 1.275 | 0.978 [0.955] |
| Antimonene | 0.6 | (0.8) | 0.973 | — | 1.170 | 0.904 [0.802] |

| | | | | | |
|---|---|---|---|---|---|
| Bismuthene | 1.5 | 2.25 | — | 1.3 | 0.707 [0.568] |

Assuming dz ≈ z and sinθ ≈ 1 for quasi-planar/low-buckled honeycomb lattice).
Similar to other group-IV and V elements, a normalization factor of 3/2 is assumed for bismuthene compared to the free atomic SOI.

Modelling results for an NC-TQFET which is a strongly spin-orbit coupled version of BLG with similar screening properties but S*=0.57, equivalent to the spin-orbit parameters for bismuthene, yield an E_{g}(V_{g}) given by the solid upper curve in FIG. 4.

FIG. 4 also allows a comparison between the modelled NC-TQFET with a hypothetical low voltage Complementary metal-oxide-semiconductor device (CMOS LV) which corresponds to a gate-all-around field effect transistor (GAAFET) at the 2018 node (metal-1 half-pitch F=15 nm). CMOS LV characteristics are V_{g}=0.3 V, on current Iₒₙ=3.2 μA, on-off ratio Iₒₙ/I_{off}=1.3×10⁴, intrinsic device switching energy Eᵢₙₜ=3.62 aJ and intrinsic delay time τ=3.8 ps. For the purpose of the comparison, the inventors have assumed that the off current is I_{off}=Iₒₙexp(−E_{g}/kT) where the Iₒₙ is the current at E_{g}=0, kT=26 meV is the thermal energy at room temperature, which corresponds to E_{g}=245 meV. From FIG. 4 it can be seen that BLG has E_{g}=245 meV at V_{g}=0.213 V, only a modest improvement over CMOS LV. However, the modelled bismuthene NC-TQFET has E_{g}=245 meV at V_{g}=0.030 V. This represents an order-of-magnitude improvement over CMOS LV.

For the purpose of the modelling, the inventors have further assumed that the NC-TQFET has a width F and gate length F=15 nm. The on-state occurs at zero bandgap, where the BLG is a massive Dirac semimetal with a conductivity approximately 4 e²/h and conductance 155 μS. Drain voltage V_{d}=V_{g}=0.030 V gives Iₒₙ=4.6 μA, similar to CMOS LV. The gate charge Q is 6.0×10⁻¹⁷ C=374 e, where e is the elemental charge, and the intrinsic switching energy Eᵢₙₜ=(¼)QV_{g}=0.45 aJ. The channel resistance R=6.45 kOhms, and gate capacitance C=Q/V_{g}=2000 aF, giving the switching time τ=(RC)=13 ps. The intrinsic switching energy of 0.45 aJ is almost an order of magnitude lower than CMOS LV.

As shown in FIG. 4, if a ferroelectric with a higher remnant polarization is used, such as BiFeO₃ (Pᵣ=130 μC/cm²) then a larger bandgap may be achieved at smaller gate voltages (dotted lines).

The NC-TQFET points to a general strategy to realize a new type of low-voltage transistor. The operating parameters of such a transistor are set by the materials parameters of the 2D TI and ferroelectric layers, and there appears to be no fundamental lower bound to the subthreshold swing for such a device.

It will be understood that the invention disclosed and defined in this specification extends to all alternative combinations of two or more of the individual features mentioned or evident from the text or drawings. All of these different combinations constitute various alternative aspects of the invention.

1. A structure comprising: a top gate electrode and a bottom gate electrode, a channel layer formed from a channel material with a band gap modulable by electric field, the channel layer being electrically insulated from the top gate electrode and the bottom gate electrode and being located adjacent to at least one layer of a negative capacitance material.

2. A structure comprising:
a top gate electrode and a bottom gate electrode,
a planar channel layer located between the top gate electrode and the bottom gate electrode, the planar channel layer being separated from the top gate electrode by a first insulating layer and separated from the bottom gate electrode by a second insulating layer;
wherein the planar channel layer is formed from a channel material with a band gap modulable by electric field;
wherein at least one of the first insulating layer and the second insulating layer are formed from a negative capacitance material.

3. The structure of claim 2, wherein both of the first insulating layer and the second insulating layers are formed from the ferroelectric material.

4. The structure of claim 2, wherein the negative capacitance material exhibits negative capacitance and wherein the channel material exhibits positive capacitance, and the combined capacitance of the channel layer, the first insulating layer, and second insulating layer is greater than 0.

5. The structure of claim 2, wherein the first insulating layer and the second insulating layer are each in physical contact with the planar channel layer, the first insulating layer being arranged on a first side of the planar channel layer and the second insulating layer being arranged on a second side of the planar channel layer.

6. The structure of claim 1, wherein the top gate and the bottom gate are operable independently of one another.

7. The structure of claim 1, wherein the structure further comprises a source electrode in electrical contact with the channel layer, and a drain electrode spaced apart from the source electrode and in electrical contact with the channel layer.

8-9. (canceled)

10. The structure of claim 1, wherein the top gate electrode and the bottom gate electrode are configured to apply an electric field across the channel layer in a direction perpendicular to a plane of the channel layer.

11. The structure of claim 1, wherein the channel material is selected from the group consisting of: few-layer graphene, a two-dimensional semiconductor, or a topological material.

12-16. (canceled)

17. The structure of claim 2, wherein the planar channel layer is in the form of a thin film having a thickness of less than 10 nm.

18. The structure of claim 1, wherein the structure is a field effect transistor or a component thereof.

19. A method of operating a structure according to claim 1, the method comprising:
applying or modulating a gate voltage to the top gate electrode and/or the bottom gate electrode to generate or vary an electric field across the channel layer in a direction perpendicular to a plane of the channel layer to alter the bandgap of the channel material in the channel layer.

20. The method of claim 19, wherein altering the bandgap of the channel layer further comprises switching the channel material between a trivial state and a non-trivial or topological state.

21. (canceled)

22. An electrical device comprising the structure according to claim 1.

23. The structure of claim 2, wherein the top gate and the bottom gate are operable independently of one another.

24. The structure of claim 2, wherein the structure further comprises a source electrode in electrical contact with the channel layer, and a drain electrode spaced apart from the source electrode and in electrical contact with the channel layer.

25. The structure of claim 2, wherein the top gate electrode and the bottom gate electrode are configured to apply an electric field across the channel layer in a direction perpendicular to a plane of the channel layer.

26. The structure of claim 2, wherein the channel material is selected from the group consisting of: few-layer graphene, a two-dimensional semiconductor, or a topological material.

27. The structure of claim 2, wherein the structure is a field effect transistor or a component thereof.

28. An electrical device comprising the structure according to claim 2.
